(19) United States
(12) Patent Application Publication
(10) Pub. No.: US 2013/0093102 A1
(43) Pub. Date: Apr. 18, 2013

(54) SEMICONDUCTOR PACKAGES AND METHODS OF MANUFACTURING THE SAME

(71) Applicants: EUN-HEE JUNG, Cheonan-si (KR); Hee Chul Lee, Cheonan-si (KR)

(72) Inventors: EUN-HEE JUNG, Cheonan-si (KR); Hee Chul Lee, Cheonan-si (KR)

(21) Appl. No.: 13/604,371

(22) Filed: Sep. 5, 2012

(30) Foreign Application Priority Data
Oct. 18, 2011 (KR) 10-2011-0106454

(51) Int. Cl. H01L 23/48

(52) U.S. Cl. 257/777; 257/E23.01

(57) ABSTRACT

Semiconductor packages are provided. The semiconductor package includes a package substrate. A semiconductor chip structure is mounted on the package substrate and includes a plurality of semiconductor chips. A molding member covers the semiconductor chip structure and the package substrate. The plurality of semiconductor chips are vertically stacked and stepped toward one direction. A thickness of an uppermost semiconductor chip of the plurality of semiconductor chips is greater than an average thickness of the other semiconductor chips thereunder. Related methods are also provided.

### CROSS-REFERENCE TO RELATED APPLICATIONS

This application claims priority under 35 U.S.C. §119 to Korean Patent Application No. 10-2011-0106454, filed on Oct. 18, 2011, the disclosure of which is hereby incorporated by reference in its entirety.

### TECHNICAL FIELD

The present disclosure relates to semiconductors, and more particularly, to semiconductor packages and methods of manufacturing the same.

### DISCUSSION OF RELATED ART

In the electronics industry, technologies for mounting a plurality of semiconductor chips in a single package are increasingly in use with the development of lighter, smaller, faster, multi-functional, and higher performance electronic systems. One such technology for mounting a plurality of semiconductor chips in a single package is known as multi-stack packaging. A multi-stack semiconductor package may include a plurality of semiconductor chips vertically stacked on a package substrate. As the number of the stacked semiconductor chips increases, there may be some difficulties in forming a molding member for protecting the semiconductor chips.

### SUMMARY

Exemplary embodiments are directed to semiconductor packages and methods of manufacturing the same.

According to some exemplary embodiments, a semiconductor package includes a package substrate, a semiconductor chip structure mounted on the package substrate and include a plurality of semiconductor chips, and a molding member covering the semiconductor chip structure and the package substrate. The plurality of semiconductor chips are vertically stacked and laterally shifted toward one direction and have a step form, and a thickness of an uppermost semiconductor chip of the plurality of semiconductor chips is greater than an average thickness of the other semiconductor chips thereunder.

A thickness of the uppermost semiconductor chip may be equal to or greater than 1.5 times an average thickness of the other semiconductor chips and may be equal to or less than 2.5 times the average thickness of the other semiconductor chips.

Each of the plurality of semiconductor chips may include chip pads on a first end thereof and the plurality of semiconductor chips may be vertically stacked and laterally shifted such that the chip pads of the plurality of semiconductor chips are exposed.

The semiconductor chip structure may include a first semiconductor chip disposed adjacent to the package substrate and may have a first thickness, second to (N−1)^{th} semiconductor chips sequentially stacked on the first semiconductor chip may have a second thickness, and an N^{th} semiconductor chip disposed on the (N−1)^{th} semiconductor chip may have a third thickness. The N^{th} semiconductor chip may be the uppermost semiconductor chip. The third thickness may be equal to or greater than twice the second thickness and may be equal to or less than two and half times the second thickness, and the first thickness may be greater than the second thickness.

The semiconductor chip structure may be a first semiconductor chip structure and semiconductor package may further include at least one additional semiconductor chip structure stacked on the first semiconductor chip structure opposite to the package substrate. In this case, each of the first semiconductor chip structure and the at least one additional semiconductor chip structure may include a lowermost semiconductor chip having a first thickness and at least one intermediate semiconductor chip having a second thickness on the lowermost semiconductor chip. The first thickness may be greater than the second thickness. The first thickness may be equal to or greater than twice the second thickness and may be equal to or less than two and half times the second thickness. Each of the semiconductor chip structures may include at least one odd-numbered semiconductor chip structure and at least one even-numbered semiconductor chip structure which are alternately stacked. The semiconductor chips of the at least one odd-numbered semiconductor chip structure may be vertically stacked and may be laterally shifted toward a first direction, and the semiconductor chips of the at least one even-numbered semiconductor chip structure may be vertically stacked and may be laterally shifted toward a second direction opposite to the first direction.

The semiconductor chip structure may further include chip adhesion films between the semiconductor chips and between the package substrate and the semiconductor chip structure.

The semiconductor package may further include a connection member electrically connecting the package substrate to the semiconductor chip structure. The semiconductor package may further include an external terminals electrically connected to the package substrate.

According to exemplary embodiments, a method of manufacturing a semiconductor device includes forming a semiconductor chip structure including a plurality of semiconductor chips that are vertically stacked on a front surface of a package substrate and are laterally shifted toward one direction and may have a step configuration. A liquid source material is supplied onto a surface of the package substrate and the front surface of the semiconductor chip structure. The liquid source material is cured and may form a molding member covering the semiconductor chip structure. A thickness of an uppermost semiconductor chip of the plurality of semiconductor chips is greater than an average thickness of the semiconductor chips under the uppermost semiconductor chip.

Supplying the liquid source material may include providing a mold frame including a first body and a second body, attaching a back surface of the package substrate to the first body, providing the liquid source material in the second body, and moving the first body toward the second body to dip the semiconductor chip structure into the liquid source material. The first and second bodies may be removed after curing the liquid source material.

The method may further include forming a connection member that electrically connects the package substrate to the semiconductor chip structure before the liquid source material is supplied. External terminals electrically connected to the package substrate may also be formed.

The thickness of the uppermost semiconductor chip may be equal to or greater than 1.5 times the average thickness of the semiconductor chips under the uppermost semiconductor chip and may be equal to or less than 2.5 times the average thickness of the semiconductor chips under the uppermost semiconductor chip.

### BRIEF DESCRIPTION OF THE DRAWINGS

The above and other features and aspects of the disclosure will become more apparent in view of the attached drawings and accompanying detailed description.

FIG. 1 is a cross sectional view illustrating a semiconductor package according to an exemplary embodiment of the present invention.

FIG. 2 is a cross sectional view illustrating a semiconductor package according to another exemplary embodiment of the present invention.

FIGS. 3 to 7 are cross sectional views illustrating a method of manufacturing a semiconductor package according to an exemplary embodiment of the present invention.

FIGS. 8A and 8B are cross sectional views illustrating a process of forming a molding member of FIG. 7.

FIGS. 9A to 9C are cross sectional pictures illustrating semiconductor packages fabricated having dimensions listed in table 1.

FIG. 10 is a graph showing heights of uppermost inclined semiconductor chips of semiconductor packages illustrated in FIGS. 9A, 9B and 9C.

FIG. 11 is a graph showing heights of uppermost inclined semiconductor chips of semiconductor packages fabricated having dimensions listed in table 2.

FIG. 12A is a schematic block diagram illustrating an example of memory cards including semiconductor packages according to some exemplary embodiments of the present invention.

FIG. 12B is a schematic block diagram illustrating an example of information processing systems including semiconductor packages according to some exemplary embodiments of the present invention.

### DETAILED DESCRIPTION

Exemplary embodiments of the present invention are described below with reference to the accompanying drawings. Many different forms and embodiments are possible without deviating from the spirit and teachings of this disclosure and so the disclosure should not be construed as limited to the exemplary embodiments set forth herein. Like reference numbers may refer to like elements throughout.

It will be understood that when an element is referred to as being “coupled,” “connected,” or “responsive” to, or “on,” another element, it can be directly coupled, connected, or responsive to, or on, the other element, or intervening elements may also be present.

Exemplary embodiments of the inventive concepts are described herein with reference to cross-sectional illustrations that are schematic illustrations of idealized embodiments (and intermediate structures) of exemplary embodiments. In the drawings, the sizes and thicknesses of layers and regions may be exaggerated for clarity. As such, variations from the shapes of the illustrations as a result, for example, of manufacturing techniques and/or tolerances, are to be expected. Thus, exemplary embodiments of the inventive concepts should not be construed as limited to the particular shapes of regions illustrated herein, but are to include deviations in shapes that result, for example, from manufacturing. For example, a region illustrated as a rectangle may have rounded or curved features. Thus, the regions illustrated in the figures are schematic in nature and their shapes are not intended to illustrate the actual shape of a region of a device and are not intended to limit the scope of exemplary embodiments.

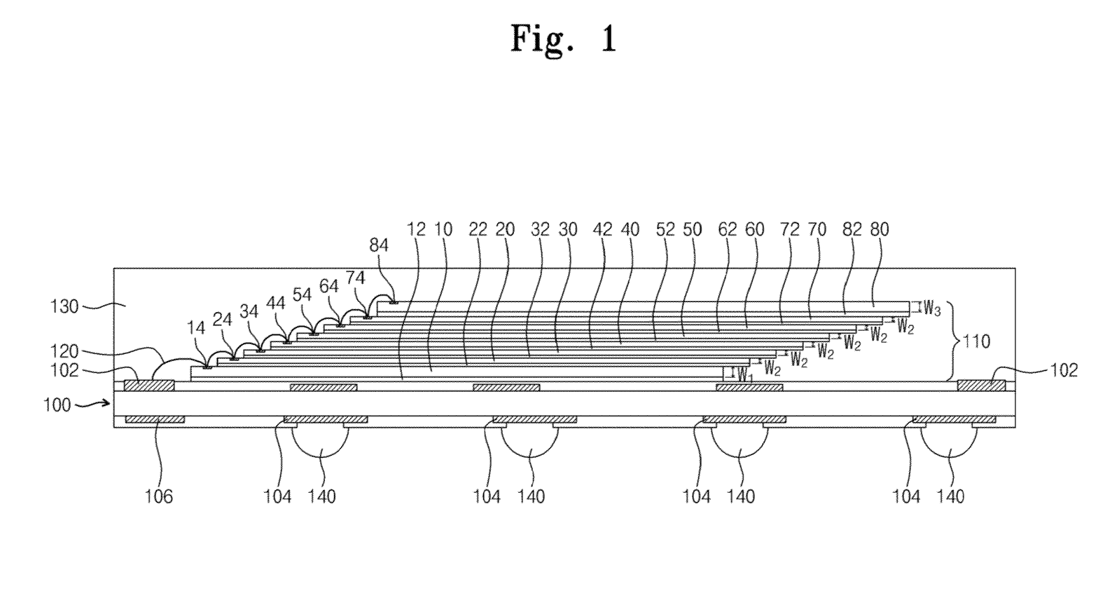

FIG. 1 is a cross sectional view illustrating a semiconductor package according to an exemplary embodiment of the present invention.

Referring to FIG. 1, a semiconductor package may include a package substrate 100, a semiconductor chip structure 110, a connection member 120, a molding member 130 and external terminals 140.

The package substrate 100 may be a printed circuit board (PCB). The package substrate 100 may include a first surface on which the semiconductor chip structure 110 is mounted and a second surface opposite to the first surface. First pads 102 may be disposed on the first surface of the package substrate 100. The first pads 102 may be electrically connected to the semiconductor chip structure 110. Second pads 104 may be disposed on the second surface of the package substrate 100, and the second pads 104 may be electrically connected to the external terminals 140. A plurality of circuit patterns 106 may be disposed in the package substrate 100.

The semiconductor chip structure 110 may be mounted on the first surface of the package substrate 100. The semiconductor chip structure 110 may include a plurality of semiconductor chips 10, 20, 30, 40, 50, 60, 70 and 80 and chip adhesion films 12, 22, 32, 42, 22, 32, 42, 52, 62, 72 and 82 disposed between the semiconductor chips 10, 20, 30, 40, 50, 60, 70 and 80. The semiconductor chips 10, 20, 30, 40, 50, 60, 70 and 80 may be vertically stacked on the first surface of the package substrate 100.

Chip pads 14, 24, 34, 44, 54, 64, 74 and 84 may be disposed on respective first ends of the semiconductor chips 10, 20, 30, 40, 50, 60, 70 and 80. The semiconductor chips 10, 20, 30, 40, 50, 60, 70 and 80 may be sequentially stacked and may be laterally shifted toward one direction such that the chip pads 14, 24, 34, 44, 54, 64, 74 and 84 are at least partially exposed.

According to an embodiment, a thickness W3 of an uppermost semiconductor chip 80 may be substantially greater than an average thickness of the other semiconductor chips 10, 20, 30, 40, 50, 60 and 70 disposed under the uppermost semiconductor chip 80. The semiconductor chip structure 110 is described more fully below.

The connection member 120 may electrically connect the semiconductor chip structure 110 to package substrate 100. For example, the connection member 120 may include bonding wires. Some of the bonding wires may electrically connect the semiconductor chips 10, 20, 30, 40, 50, 60, 70 and 80 to each other, and the rest of the bonding wires may electrically connect the semiconductor chips 10, 20, 30, 40, 50, 60, 70 and 80 to the package substrate 100.

A molding member 130 may be disposed covering the semiconductor chip structure 110 and the first surface of the package substrate 100. The molding member 130 may include an epoxy molding compound (EMC) material. The external terminals 140 may be disposed on the second pads 104 opposite to the package substrate 100. For example, the external terminals 140 may be electrically connected to the second pads 104. The external terminals 140 may be solder balls.

The semiconductor chip structure 110 is described in detail hereinafter. For the purpose of ease and convenience in explanation, the following exemplary embodiment is described in conjunction with an example in which the semiconductor chip structure 110 includes eight semiconductor chips 10, 20, 30, 40, 50, 60, 70 and 80. However, the semiconductor chip structure 110 may include between two and eight semiconductor chips or it may include nine or more semiconductor chips.

A lowermost semiconductor chip 10 may be referred to as a first semiconductor chip and an uppermost semiconductor chip 80 may be referred to as an eighth semiconductor chip. The first semiconductor chip 10 may have a first thickness W1 and may be adhered to the package substrate by a first chip adhesion film 12.

Second to seventh semiconductor chips 20, 30, 40, 50, 60 and 70 may be sequentially stacked between the first and eighth semiconductor chips 10 and 80. The second to seventh semiconductor chips 20, 30, 40, 50, 60 and 70 may be sequentially stacked and may have a step configuration such that the first and sixth chip pads 14, 24, 34, 44, 54 and 64 are at least partially exposed. Second to seventh chip adhesion films 22, 32, 42, 52, 62 and 72 may be disposed among the first to seventh semiconductor chips 10, 20, 30, 40, 50, 60 and 70 such that the first to seventh semiconductor chips 10, 20, 30, 40, 50, 60 and 70 adhere to each other.

Each of the second to seventh semiconductor chips 20, 30, 40, 50, 60 and 70 may have a second thickness W2. The second thickness W2 may be substantially less than the first thickness W1. For example, first thickness W1 may be equal to or greater than twice the second thickness W2 and may be equal to or less than two and half times the second thickness W2. For example, the second thickness W2 may be within the range of about 15 micrometers to about 25 micrometers.

However, it should be understood that each of the second to seventh semiconductor chips 10, 20, 30, 40, 50, 60 and 70 need not exactly be of the second thickness and that the second to seventh semiconductor chips 10, 20, 30, 40, 50, 60 and 70 may instead have an average thickness of W2. However, according to other exemplary embodiments of the present invention, each of the second to seventh semiconductor chips 10, 20, 30, 40, 50, 60 and 70 may have a thickness of W2 or less.

The eighth semiconductor chip 80 may also be stacked on the seventh semiconductor chip 70 and may be laterally shifted toward one direction such that the seventh chip pad 74 is at least partially exposed. An eighth chip adhesion film 82 may be disposed between the seventh and eighth semiconductor chips 70 and 80 such that the seventh and eighth semiconductor chips 70 and 80 adhere to each other.

The eighth semiconductor chip 80 may have a third thickness W3. The third thickness W3 may be substantially greater than the second thickness W2. The third thickness W3 may be equal to or greater than twice the second thickness W2 and may be equal to or less than two and half times the second thickness W2. According to an exemplary embodiment, the eighth semiconductor chip 80 may have a thickness which is equal to or greater than 1.5 times an average thickness of the second to seventh semiconductor chips 20 to 70 and which is equal to or less than 2.5 times the average thickness of the second to seventh semiconductor chips 20 to 70.

Although the present embodiment is described in conjunction with the semiconductor chip structure 110 including eight steps of stacked semiconductor chips 10, 20, 30, 40, 50, 60, 70 and 80, as described above, the number of the stacked semiconductor chips is not limited to eight.

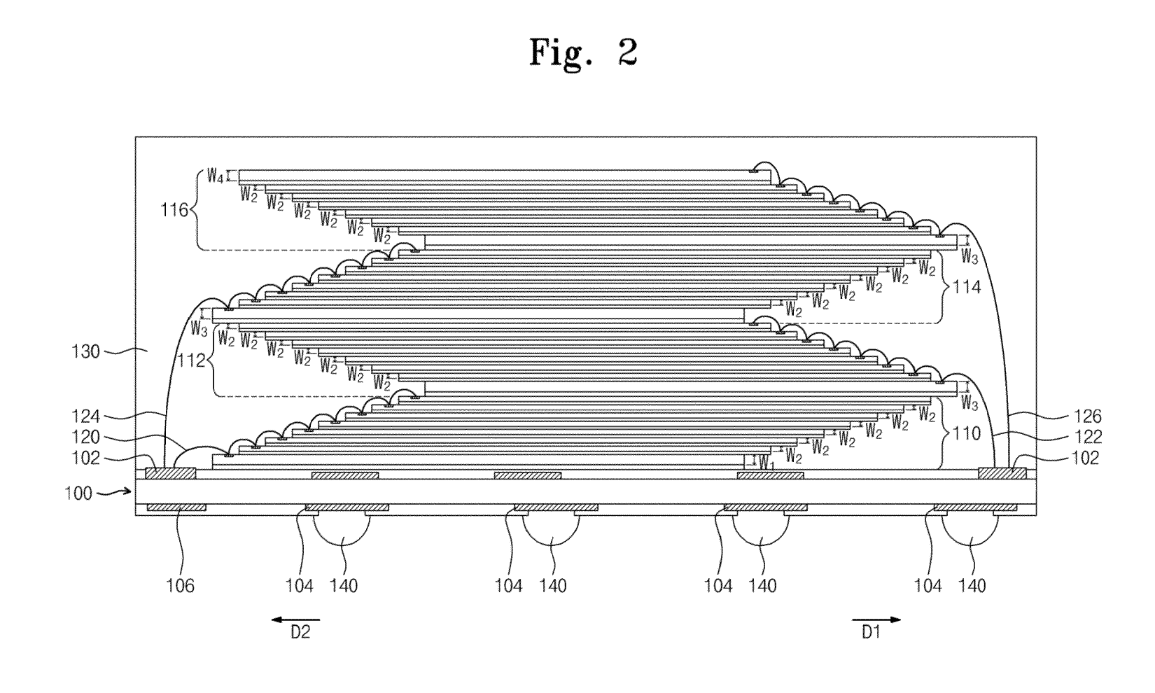

FIG. 2 is a cross sectional view illustrating a semiconductor package according to an exemplary embodiment of the present invention.

Referring to FIG. 2, a semiconductor package may include a package substrate 100, first to fourth semiconductor chip structures 110, 112, 114 and 116, first to fourth connection members 120, 122, 124 and 126, a molding member 130, and external terminals 140.

Each of the first to fourth semiconductor chip structures 110, 112, 114 and 116 may include eight steps of stacked semiconductor chips. More specifically, the first semiconductor chip structure 110 may include first to eighth semiconductor chips and the first to eighth semiconductor chips may be vertically stacked and laterally shifted toward a first direction D1 and may have a step configuration. The first to eighth semiconductor chips may be adhered to each other by chip adhesion films disposed therebetween. According to an embodiment, the first fourth semiconductor chip may have a first thickness W1, and each of the second to eighth semiconductor chips may have a second thickness W2. The first thickness W1 may be substantially greater than the second thickness W2. For example, the second thickness W2 may be about 20 micrometers.

The first connection member 120 may electrically connect chip pads disposed on first ends of the first to eighth semiconductor chips to each other. Further, the first connection member 120 may electrically connect some of the chip pads of the first to eighth semiconductor chips to first pads 102 disposed on a first surface of the package substrate 100.

The second semiconductor chip structure 112 may include a ninth to a sixteenth semiconductor chips, and the ninth to sixteenth semiconductor chips may be vertically stacked and laterally shifted toward a second direction D2 opposite to the first direction D1 and may have a step configuration. The ninth to sixteenth semiconductor chips may be adhered to each other by chip adhesion films disposed therebetween. According to an embodiment, the ninth semiconductor chip may have a third thickness W3, and each of the tenth to sixteenth semiconductor chips may have the second thickness W2. The third thickness W3 may be substantially greater than the second thickness W2.

The second connection member 122 may electrically connect chip pads disposed on second ends of the ninth to sixteenth semiconductor chips to each other. Further, the second connection member 122 may electrically connect some of the chip pads of the ninth to sixteenth semiconductor chips to the first pads 102 disposed on the first surface of the package substrate 100.

The third semiconductor chip structure 114 may include a seventeenth to a twenty fourth semiconductor chips, and the seventeenth to twenty fourth semiconductor chips may be vertically stacked and laterally shifted toward the first direction D1 and may have a step configuration. The seventeenth to twenty fourth semiconductor chips may be adhered to each other by chip adhesion films disposed therebetween. According to an embodiment, the seventeenth semiconductor chip may have the third thickness W3, and each of the eighteenth to twenty fourth semiconductor chips may have the second thickness W2.

The third connection member 124 may electrically connect chip pads disposed on first ends of the seventeenth to twenty fourth semiconductor chips to each other. Further, the third connection member 124 may electrically connect some of the chip pads of the seventeenth to twenty fourth semiconductor chips to the first pads 102 disposed on the first surface of the package substrate 100.

The fourth semiconductor chip structure 116 may include a twenty fifth to a thirty second semiconductor chips, and the twenty fifth to thirty second semiconductor chips may be vertically stacked and laterally shifted toward the second direction D2 and may have a step configuration. The twenty fifth to thirty second semiconductor chips may be adhered to each other by chip adhesion films disposed therebetween. According to an embodiment, the twenty fifth semiconductor chip may have the third thickness W3, and each of the twenty sixth to thirty first semiconductor chips may have the second thickness W2. In an embodiment, an uppermost semiconductor chip in the first to fourth semiconductor chip structures 110, 112, 114 and 116, for example, the thirty second semiconductor chip may have a fourth thickness W4. The fourth thickness W4 may be equal to or greater than twice the second thickness W2 and may be equal to or less than two and half times the second thickness W2. According to an embodiment, the fourth thickness W4 may be equal to or greater than 1.5 times an average thickness of the first to thirty first semiconductor chips and may be equal to or less than 2.5 times the average thickness of the first to thirty first semiconductor chips.

The fourth connection member 126 may electrically connect chip pads disposed on second ends of the twenty fifth to thirty second semiconductor chips to each other. Further, the fourth connection member 126 may electrically connect some of the chip pads of the twenty fifth to thirty second semiconductor chips to the first pads 102 disposed on the first surface of the package substrate 100.

The package substrate 100, the molding member 130 and the external terminals 140 may have substantially the same configurations as described above with reference to FIG. 1.

As described above, in each of the semiconductor chip structures, the thickness of the uppermost semiconductor chip may be substantially greater than the average thickness of the other semiconductor chips. Thus, the uppermost semiconductor chips of the semiconductor chip structures may be designed to withstand the load of the molding member 130 without any warpage or damage thereof.

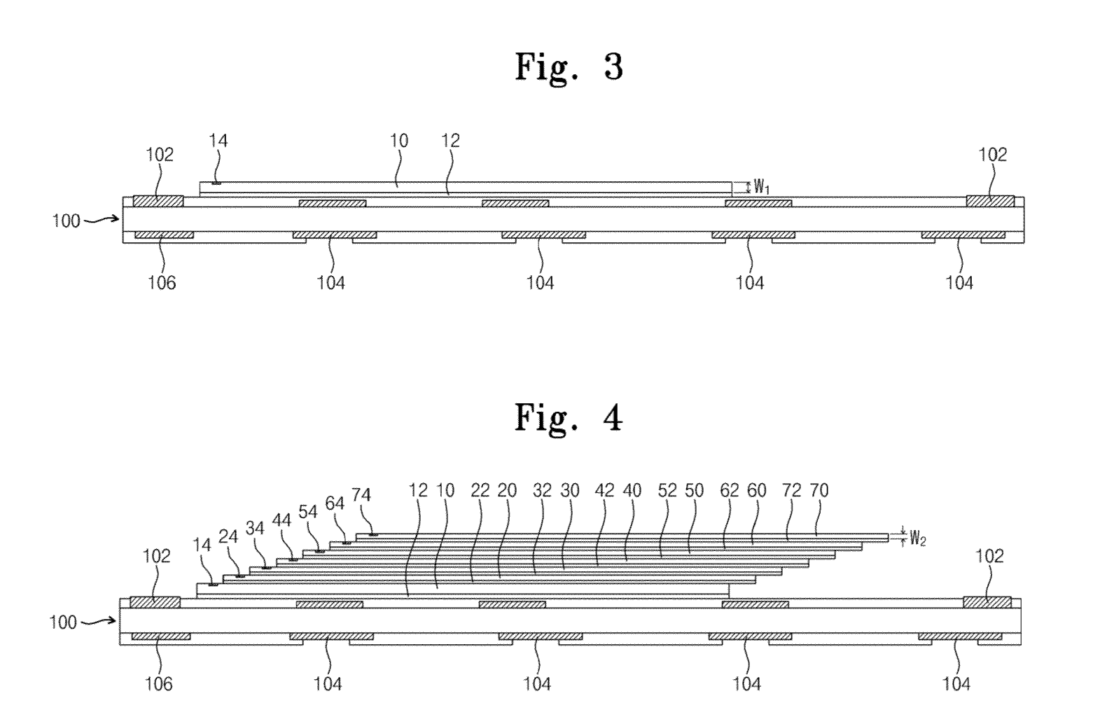

FIGS. 3 to 7 are cross sectional views illustrating a method of manufacturing a semiconductor package according to an exemplary embodiment.

Referring to FIG. 3, a first semiconductor chip 10 may be adhered to a first surface of a package substrate 100 using a first chip adhesion film 12.

The package substrate 100 may include circuit patterns formed 106 therein and/or thereon. First pads 102 may be formed on the first surface of the package substrate 100, and second pads 104 may be formed on a second surface of the package substrate 100 opposite to the first surface. The first pads 102 may include a plurality of pads, and second pads 106 may also include a plurality of pads.

First chip pads 14 may be formed on a first end of the first semiconductor chip 10. The first semiconductor chip 10 may have a first thickness W1.

Referring to FIG. 4, second to seventh semiconductor chips 20, 30, 40, 50, 60 and 70 may be vertically and sequentially stacked on the first semiconductor chip 10 opposite to the package substrate 100. The first to seventh semiconductor chips 10, 20, 30, 40, 50, 60 and 70 may be adhered to each other using second to seventh chip adhesion films 22, 32, 42, 52, 62 and 72.

Second to seventh chip pads 24, 34, 44, 54, 64 and 74 may be formed on respective first ends of the second to seventh semiconductor chips 20, 30, 40, 50, 60 and 70. Thus, the second to seventh semiconductor chips 20, 30, 40, 50, 60 and 70 may be vertically stacked and laterally shifted toward a first direction such that the second to seventh chip pads 24, 34, 44, 54, 64 and 74 are at least partially exposed.

The second to seventh semiconductor chips 20, 30, 40, 50, 60 and 70 may have substantially the same thickness, for example, a second thickness W2. The second thickness W2 may be less than the first thickness W1. The first thickness W1 may be equal to or greater than twice the second thickness W2 and may be equal to or less than two and half times the second thickness W2. For example, the second thickness W2 may be within the range of about 15 micrometers to about 25 micrometers.

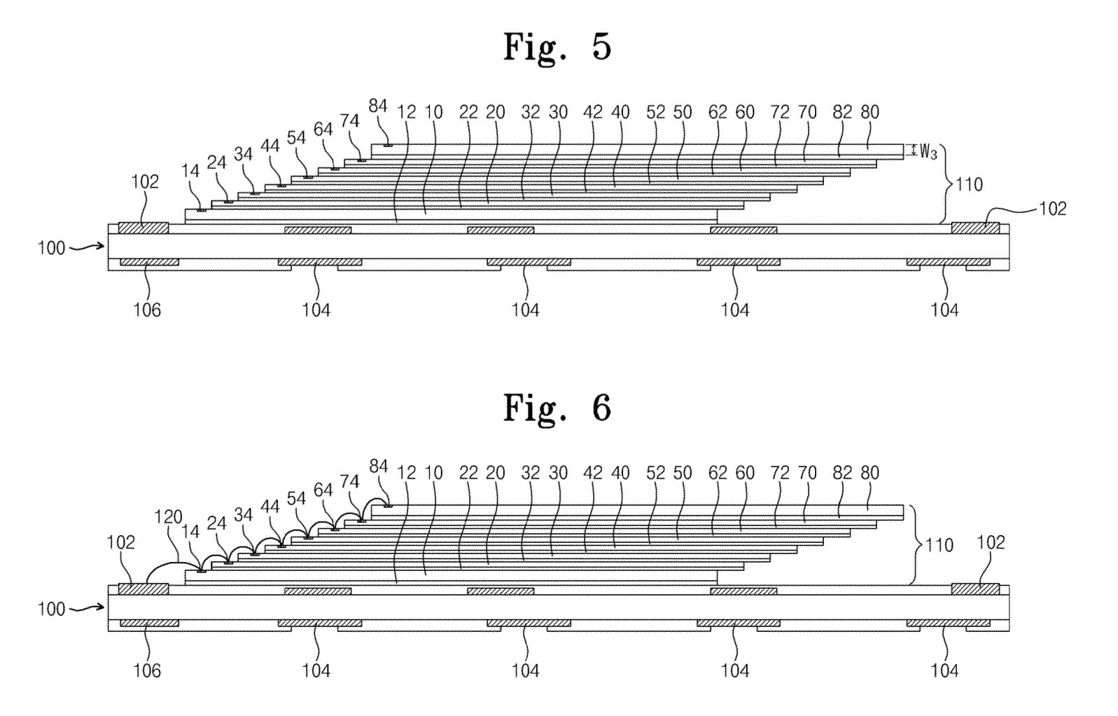

Referring to FIG. 5, an eighth semiconductor chip 80 may be stacked on the seventh semiconductor chip 70 opposite to the sixth semiconductor chip 60. The eighth semiconductor chip 80 may be adhered to the seventh semiconductor chip 70 using an eighth chip adhesion film 82. The eighth semiconductor chip 80 may be laterally shifted toward the first direction such that the seventh chip pads 74 are at least partially exposed.

Eighth chip pads 84 may be formed on a first end of the eighth semiconductor chip 80. The eighth semiconductor chip 80 may have a third thickness

W3. The third thickness W3 may be greater than the first thickness W1. The third thickness W3 may be equal to or greater than twice the first thickness W1 and may be equal to or less than two and half times the first thickness W1. According to an embodiment, the third thickness W3 may be equal to or greater than 1.5 times an average thickness of the second to seventh semiconductor chips 20 to 70 and may be equal to or less than 2.5 times the average thickness of the second to seventh semiconductor chips 20 to 70.

As such, a semiconductor chip structure 110 may be formed including the first to eighth semiconductor chips 10, 20, 30, 40, 50, 60, 70 and 80 vertically stacked. Although the present embodiment is described in conjunction with the semiconductor chip structure 110 including eight steps of stacked semiconductor chips 10, 20, 30, 40, 50, 60, 70 and 80, the number of the stacked semiconductor chips is not limited to eight.

Referring to FIG. 6, a connection member 120 may be formed to electrically the semiconductor chip structure 110 to the package substrate 100.

According to an embodiment, the connection member 120 may include a plurality of bonding wires. Some of the bonding wires may be formed electrically connecting the first to eighth chip pads 14, 24, 34, 44, 54, 64, 74 and 84 to each other, and the rest of the bonding wires may be formed electrically connecting the semiconductor chips 10, 20, 30, 40, 50, 60, 70 and 80 to the first pads 102 of the package substrate 100.

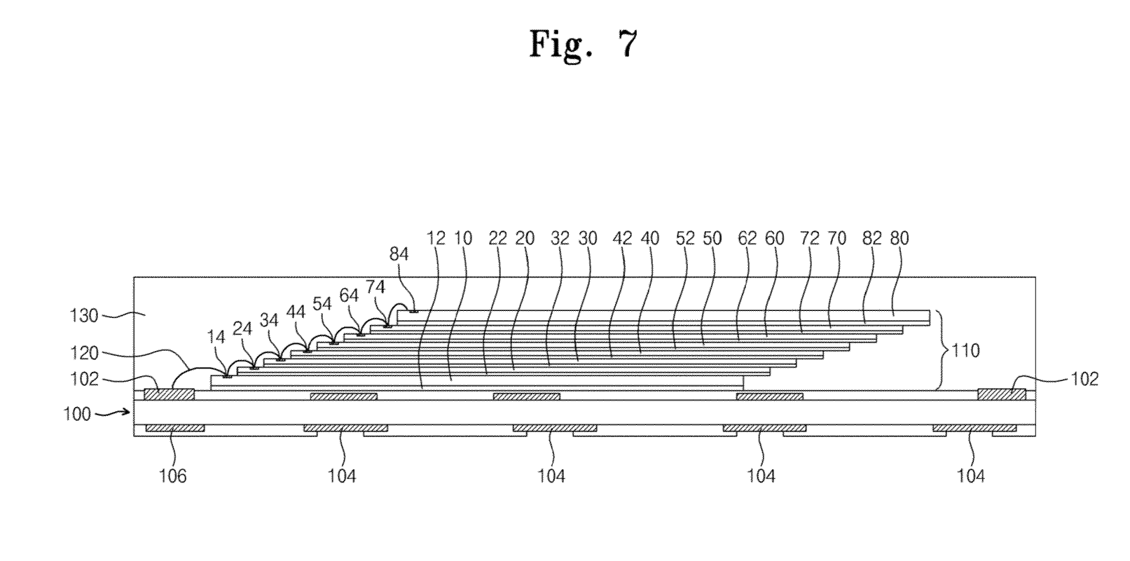

Referring to FIG. 7, a molding member 130 may be formed covering the semiconductor chip structure 110 and the first surface of the package substrate 100.

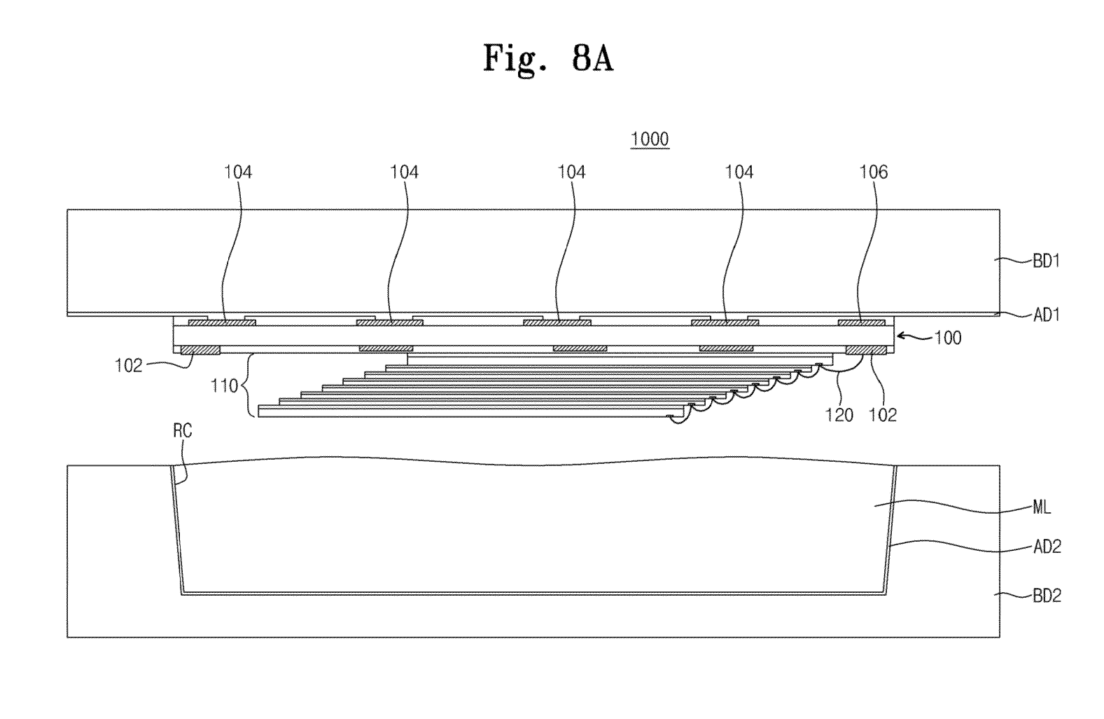

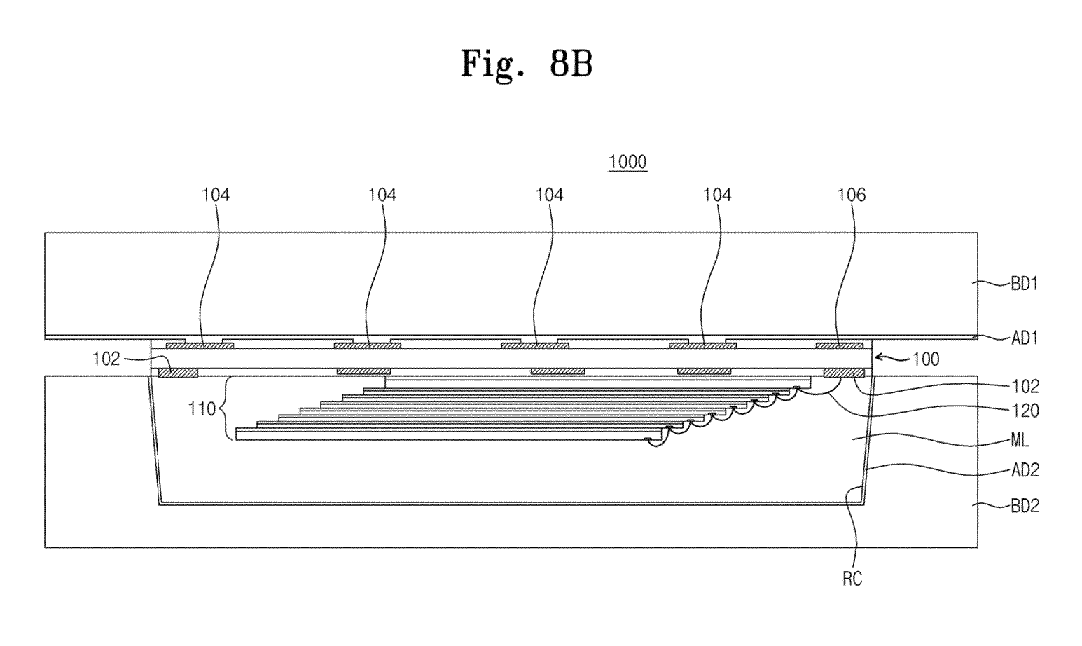

The process of forming the molding member 130 is be described below with reference to FIGS. 8A and 8B.

FIGS. 8A and 8B are cross sectional views illustrating a process of forming a molding member of FIG. 7.

Referring to FIG. 8A, a mold frame 1000 for forming the molding member 130 may be provided. The mold frame 1000 may include a first body BD1 and a second body BD2. After the semiconductor chip structure 110 is mounted on the first surface of the package substrate 100, the second surface of the package substrate 100 may be attached to the first body BD1 using a first adhesive AD1. The second body BD2 may include a recessed region RC therein, and a second adhesive AD2 may be provided along an inner surface of the recessed region RC. A liquid source material ML for forming the molding member 130 may be then supplied into the recessed region RC. For example, the liquid source material ML may be formed by melting epoxy molding compound (EMC) powder. The semiconductor chip structure 110 attached to the first body BD1 and the liquid source material ML in the recessed region RC may be disposed facing each other.

Referring to FIG. 8B, the first body BD1 may be moved toward the second body BD2 such that the semiconductor chip structure 110 is dipped into the liquid source material ML. Accordingly, the liquid source material ML may be flowed into spaces between the first to eighth semiconductor chips 10, 20, 30, 40, 50, 60, 70 and 80.

While the liquid source material ML is flowed into the spaces between the first to eighth semiconductor chips, the uppermost semiconductor chip, for example, the eighth semiconductor chip 80 may withstand stress (e.g., pressure and/or load) generated from the liquid source material ML since the thickness (e.g., the third thickness W3) of the eighth semiconductor chip 80 is greater than an average thickness of the other semiconductor chips (e.g., the first to seventh semiconductor chips). Thus, the eighth semiconductor chip 80 may prevent the semiconductor chips vertically stacked and laterally shifted on the package substrate 100 from falling down or warping toward the package substrate 100.

In addition, since the semiconductor chips withstand against the stress generated from the liquid source material ML to maintain their initial shapes, the spaces and/or gaps between the semiconductor chips may not be deformed or reduced. Accordingly, the liquid source material ML can be smoothly flowed into the spaces between the semiconductor chips without formation of voids therein.

Subsequently, the liquid source material ML may be cured forming the molding member 130, and the mold frame 1000 may be then detached or separated from the package substrate 100 and the molding member 130.

Referring again to FIG. 1, external terminals 140 may be formed on the second pads 104 opposite to the package substrate 100. The external terminals 140 may include solder balls.

Hereinafter, characteristics of the semiconductor packages fabricated according to some exemplary embodiments are compared with each other.

Some dimensions of the semiconductor packages according to some exemplary embodiments are listed in the following Table 1. All the semiconductor packages according to the exemplary embodiments according to comparative examples may be fabricated having eight stacked semiconductor chips. For example, the semiconductor packages having the dimensions listed in Table 1 may be fabricated having the configuration illustrated in FIG. 1.

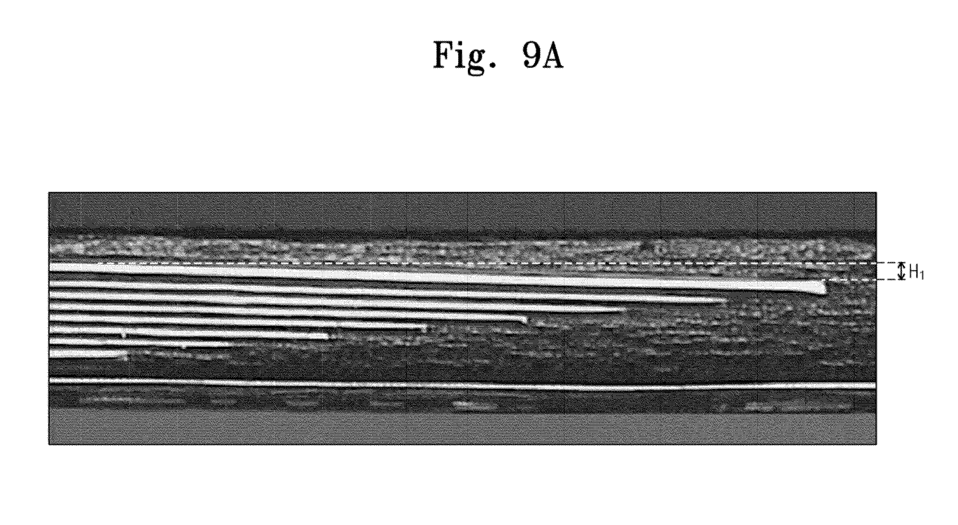

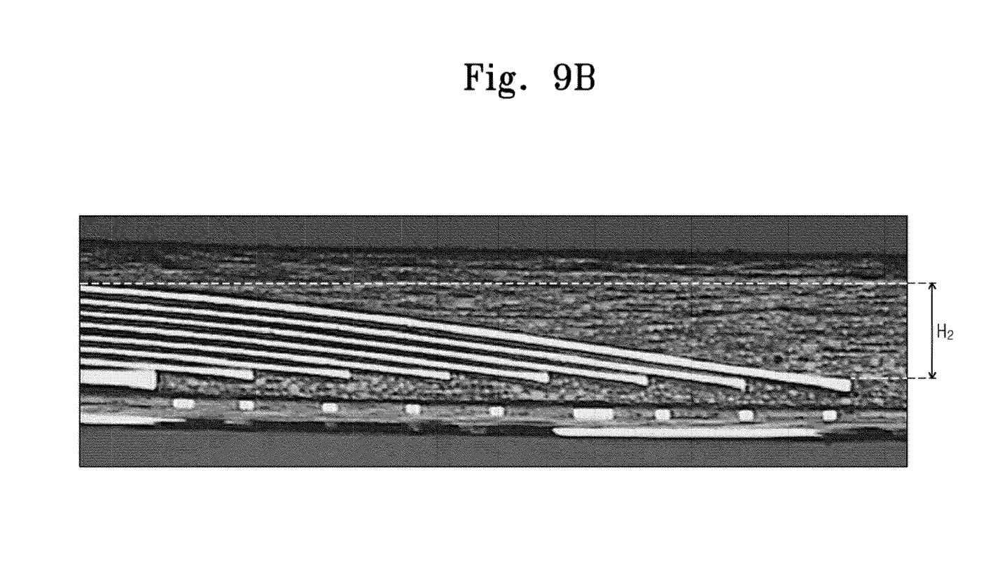

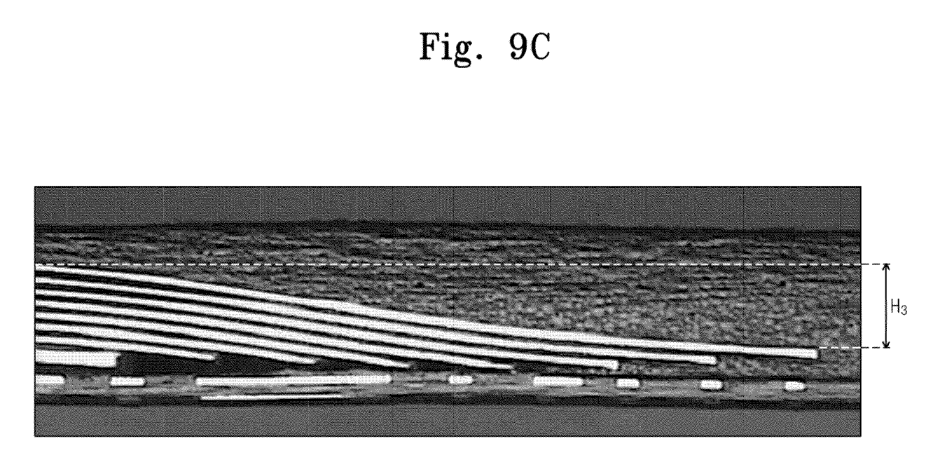

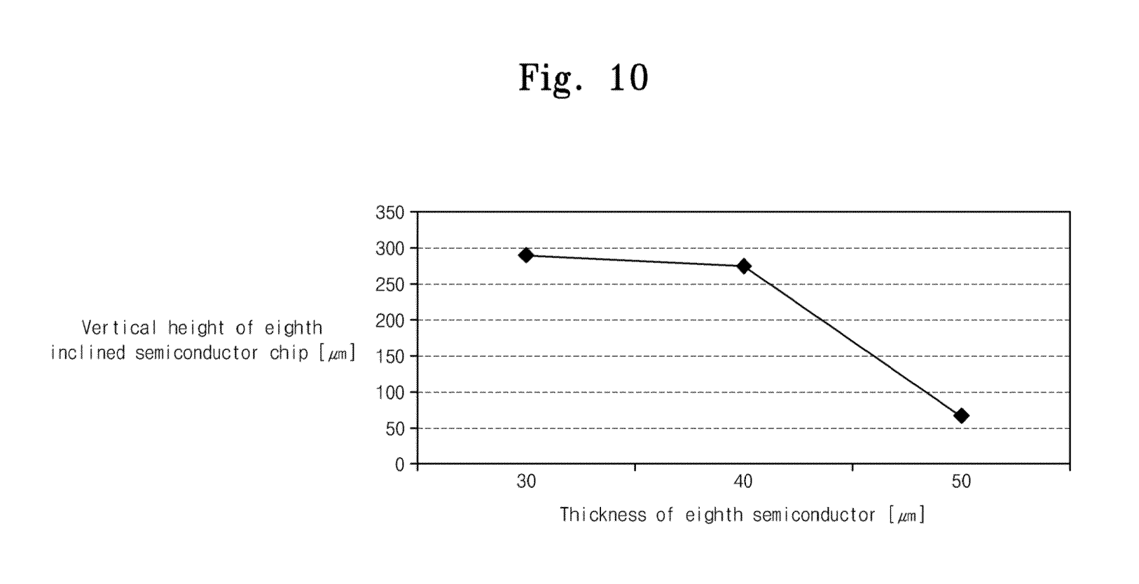

TABLE 1

| | | Comparative | Comparative |
|---|---|---|---|
| | Embodiment | Example 1 | Example 2 |
| Dimensions | (FIG. 9A) | (FIG. 9B) | (FIG. 9C) |
| Thickness of First | 60 μm | | |
| Semiconductor Chip | | | |
| Thickness of First | 25 μm | | |
| to Seventh | | | |
| Semiconductor Chips | | | |
| Thickness of Eighth | 50 μm | 40 μm | 30 μm |
| Semiconductor Chip | | | |
| Distance between | 130 μm | 140 μm | 150 μm |
| Eighth Semiconductor | | | |
| Chip and Top Surface | | | |
| of Molding Member | | | |

| | |
|---|---|
| Total Height of | 480 μm |
| Molding Member | |

Referring to Table 1, all the semiconductor packages according to exemplary embodiments may be fabricated such that the first to seventh semiconductor chips have the same thickness (e.g., 25 micrometers). The eighth semiconductor chip of the exemplary embodiment may be formed having a thickness of 50 micrometers. Further, the eighth semiconductor chip of the first comparative example may be formed having a thickness of 40 micrometers, and the eighth semiconductor chip of the second comparative example may be formed having a thickness of 30 micrometers.

In addition, while the eighth semiconductor chips according to the exemplary embodiments may be formed having different thicknesses from each other, all the molding members may still be formed having the same total height.

FIGS. 9A to 9C are cross sectional pictures illustrating semiconductor packages fabricated having the dimensions listed in table 1. FIG. 9A illustrates a semiconductor package fabricated according to an exemplary embodiment of the present invention. FIG. 9B illustrates a semiconductor package fabricated according to the first comparative example, and FIG. 9C illustrates a semiconductor package fabricated according to the second comparative example.

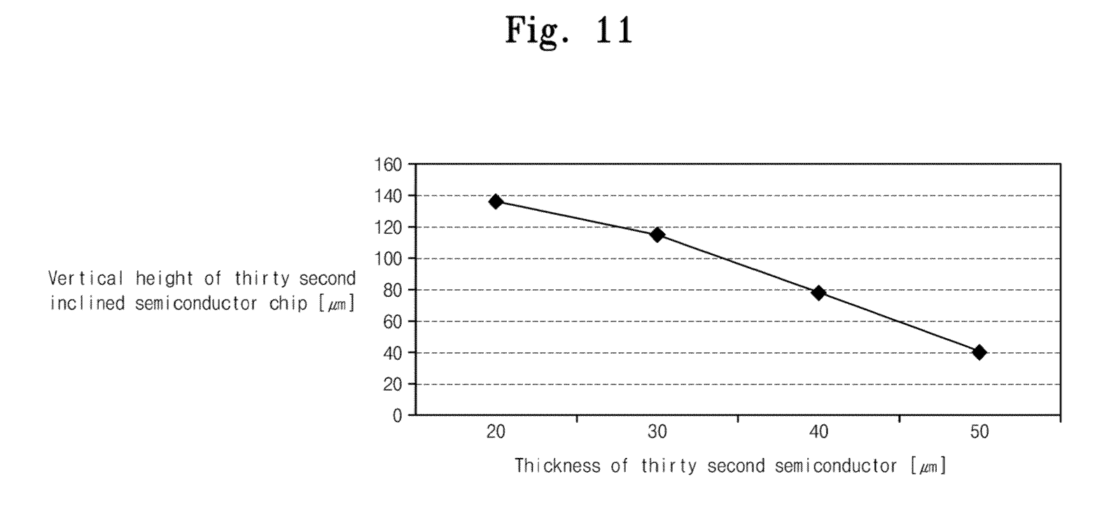

FIG. 10 is a graph showing measurement results of dimensions of the deformed uppermost semiconductor chips (e.g., the eighth semiconductor chips) illustrated in FIGS. 9A, 9B and 9C. In FIG. 10, the abscissa indicates a thickness of the uppermost semiconductor chips, and the ordinate indicates a vertical height of the deformed uppermost semiconductor chip.

Referring to FIGS. 9A and 10, the eighth semiconductor chip may be formed having a thickness of 50 micrometers. As illustrated in FIGS. 9A and 10, the eighth semiconductor chip fabricated according to the exemplary embodiment may be deformed and inclined having a total vertical height (H1) of about 67.1 micrometers during formation of the molding member.

Referring to FIGS. 9B, 9C and 10, the eighth semiconductor chip of the first comparative example may be formed having a thickness of 40 micrometers, and the eighth semiconductor chip of the second comparative example may be formed having a thickness of 30 micrometers. As illustrated in FIGS. 9B and 10, the eighth semiconductor chip fabricated according to the first comparative example may be deformed and inclined having a total vertical height (H2) of about 274.7 micrometers during formation of the molding member, and the eighth semiconductor chip fabricated according to the second comparative example may be deformed and inclined having a total vertical height (H3) of about 289.5 micrometers during formation of the molding member.

As can be seen from the above results, the uppermost semiconductor chip of the semiconductor package fabricated according to the exemplary embodiment was less deformed as compared with the uppermost semiconductor chips of the semiconductor packages fabricated according to the first and second comparative examples. This may be understood to mean that the uppermost semiconductor chip may become less damaged or warped as the thickness of the uppermost semiconductor chip increases. Further, if the uppermost semiconductor chip may become less warped, spaces between the stacked semiconductor chips may be more readily filled by the molding member without any voids.

Several dimensions of semiconductor packages according to some exemplary embodiments are listed in the following Table 2. All the semiconductor packages according to the exemplary embodiments and all the other typical semiconductor packages according to some examples may be fabricated having thirty-two stacked semiconductor chips. For example, the semiconductor packages having the dimensions listed in Table 2 may be fabricated having the configuration illustrated in FIG. 2.

TABLE 2

| | Exemplary | Compar- | Compar- | Compar- |
|---|---|---|---|---|
| | Embodi- | ative | ative | ative |
| Dimensions | ment | Example 1 | Example 2 | Example 3 |
| Thickness of First | 40 μm | | | |
| Semiconductor Chip | | | | |
| Thickness of Second | 20 μm | | | |
| to Eighth | | | | |
| Semiconductor Chips | | | | |
| Thickness of Ninth | 50 μm | | | |
| Semiconductor Chip | | | | |
| Thickness of Tenth | 20 μm | | | |
| to Sixteenth | | | | |
| Semiconductor Chips | | | | |
| Thickness of Seventeenth | 50 μm | | | |
| Semiconductor Chip | | | | |
| Thickness of Eighteenth | 20 μm | | | |
| to Twenty Fourth | | | | |
| Semiconductor Chips | | | | |
| Thickness of Twenty | 50 μm | | | |
| Fifth Semiconductor | | | | |
| Chip | | | | |
| Thickness of Twenty | 20 μm | | | |
| Sixth to Thirty First | | | | |
| Semiconductor Chips | | | | |
| Thickness of Thirty | 50 μm | 40 μm | 30 μm | 20 μm |
| Second Semiconductor | | | | |
| Chip | | | | |
| Distance between Thirty | 80 μm | 90 μm | 100 μm | 110 μm |
| Second Semiconductor | | | | |
| Chip and Top Surface | | | | |
| of Molding Member | | | | |
| Total Height of | 1220 μm | | | |
| Molding Member | | | | |
| Vertical Height of | 40 μm | 78 μm | 115 μm | 136 μm |
| Deformed Thirty Second | | | | |
| Semiconductor Chip | | | | |

Referring to Table 2, the first to thirty first semiconductor chips of the exemplary embodiment may be formed having the same thicknesses as the first to thirty first semiconductor chips of the comparative examples, respectively. Meanwhile, the uppermost semiconductor chip (e.g., the thirty second semiconductor chip) of the exemplary embodiment may be formed having a thickness of 50 micrometers. The uppermost semiconductor chips (e.g., the thirty second semiconductor chips) of the first to third comparative examples may be formed having thicknesses of 40 micrometers, 30 micrometers and 20 micrometers, respectively.

In addition, while the uppermost semiconductor chips according to the exemplary embodiment and the first to third comparative examples may be formed having different thicknesses from each other, all the molding members may be formed having the same total height (e.g., 1220 micrometers).

FIG. 11 is a graph showing measurement results of dimensions of the uppermost semiconductor chips (e.g., the thirty second semiconductor chips) deformed after formation of the molding members. In FIG. 11, the abscissa indicates a thickness of the uppermost semiconductor chips, and the ordinate indicates a vertical height of the deformed uppermost semiconductor chip.

Referring to Table 2 and FIG. 11, the thirty second semiconductor chip of the exemplary embodiment may be formed having a thickness of 50 micrometers. As illustrated in FIG. 11, the thirty second semiconductor chip of the exemplary embodiment may be deformed and inclined having a total vertical height of about 40 micrometers during formation of the molding member.

The thirty second semiconductor chips of the first to third comparative examples may be formed having thicknesses of 40 micrometers, 30 micrometers and 20 micrometers, respectively. As illustrated in FIG. 11, the thirty second semiconductor chips of the first to third comparative examples may be deformed and inclined having total vertical heights of about 78 micrometers, about 115 micrometers and about 136 micrometers during formation of the molding member, respectively.

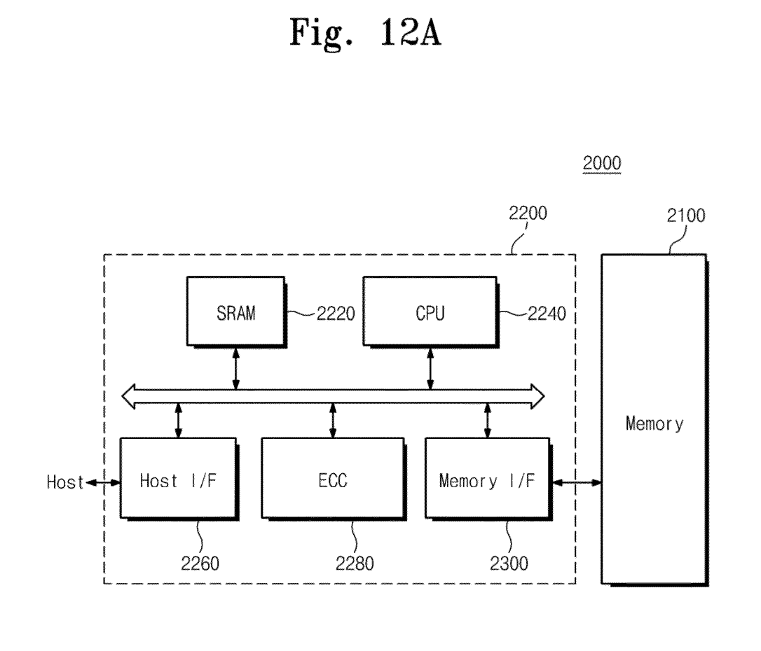

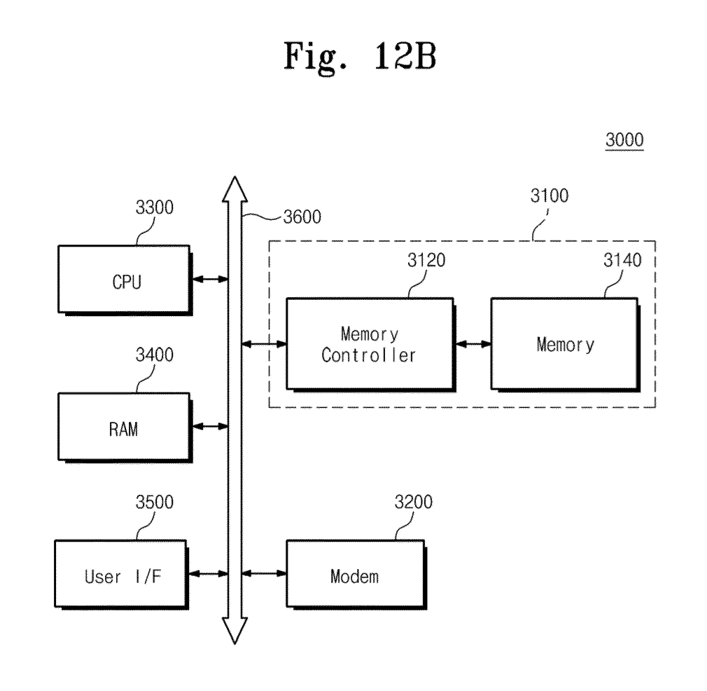

FIG. 12A is a schematic block diagram illustrating an example of memory cards including the semiconductor packages according to some exemplary embodiments of the present invention.

Referring to FIG. 12A, the semiconductor package according to exemplary embodiment may be employed in a memory card 2000. The memory card 2000 may include a memory device 2100 having at least one of the semiconductor packages according to the exemplary embodiments described above. The memory card 2000 may be used as a data storage media for storing a large capacity of data. The memory card 2000 may further include a memory controller 2200 that controls data communication between a host and the memory device 2100.

The memory controller 2200 may include a static random access memory (SRAM) device 2220, a central processing unit (CPU) 2240, a host interface unit 2260, an error check and correction (ECC) block 2280 and a memory interface unit 2300. The SRAM device 2220 may be used as an operation memory of the CPU 2240. The host interface unit 2260 may be configured including a data communication protocol between the memory card 2000 and the host. The ECC block 2280 may detect and correct errors of data which are read out from the memory device 2100. The memory interface unit 2300 may connect the memory controller 2200 to the memory device 2100. The central processing unit (CPU) 2240 may control overall operations for data communication of the memory controller 2200. Even though not shown in the drawings, the memory card 2000 may further include a read only memory (ROM) device that stores code data to interface with the host.

Since at least one of the semiconductor packages according to the exemplary embodiments is employed in the memory card 2000, reliability of the memory card 2000 may be increased.

FIG. 12B is a block diagram illustrating an example of information processing systems including the semiconductor packages according to exemplary embodiments.

Referring to FIG. 12B, an information processing system 3000 may be a mobile system such as a laptop computer, a tablet computer or a smartphone, a desktop computer or the like. The information processing system 3000 may include a memory unit 3100 having at least one of the semiconductor packages according to exemplary embodiments described above. The information processing system 3000 may further include a modulator-demodulator (MODEM) 3200, a central processing unit (CPU) 3300, a random access memory (RAM) device 3400 and a user interface unit 3500. At least two of the memory unit 3100, the MODEM 3200, the CPU 3300, the RAM device 3400 and the user interface unit 3500 may communicate with each other through a data bus 3600. The memory unit 3100 may have substantially the same configuration as the memory card 2000 illustrated in FIG. 12A. For example, the memory unit 3100 may include a memory device 3140 and a memory controller 3120 that controls overall operations of the memory device 3140.

The memory unit 3100 may store data processed by the CPU 3300 or data transmitted from an external system. The memory unit 3100 may be configured including a solid state disk (SSD). In this case, the memory unit 3100 constituting the information processing system 3000 may stably and reliably store a large capacity of data. If the reliability of the memory unit 3100 is increased, the information processing system 3000 may save resources that are required to check and correct data. Consequently, the information processing system 3000 may provide fast data communication. Even though not shown in the drawings, the information processing system 3000 may further include a camera image processor, an application chipset and/or an input/output unit.

According to the embodiments set forth above, an uppermost semiconductor chip of a plurality of stacked semiconductor chips mounted on a package substrate may be thicker than the other semiconductor chips disposed thereunder. Thus, the uppermost semiconductor chip may become less deformed while a molding member is formed covering the stacked semiconductor chips. Accordingly, a liquid source material used in formation of the molding member can be more readily flowed into spaces between the stacked semiconductor chips during formation of the molding member. Consequently, a reliable semiconductor package can be fabricated without any voids in the molding member.

While the inventive concept has been described with reference to example embodiments, it will be apparent to those skilled in the art that various changes and modifications may be made without departing from the spirit and scope of the inventive concept.

1. A semiconductor package comprising:
a package substrate;
a semiconductor chip structure mounted on the package substrate, said semiconductor chip structure comprising a plurality of semiconductor chips; and
a molding member covering the semiconductor chip structure and the package substrate,
wherein each of the plurality of semiconductor chips are vertically stacked and stepped toward one direction, and a thickness of an uppermost semiconductor chip of the plurality of semiconductor chips is greater than an average thickness of the other semiconductor chips of the plurality of semiconductor chips.

2. The semiconductor package of claim 1, wherein the thickness of the uppermost semiconductor chip is equal to or greater than 1.5 times the average thickness of the other semiconductor chips and the thickness of the uppermost semiconductor chip is equal to or less than 2.5 times the average thickness of the other semiconductor chips.

3. The semiconductor package of claim 1, wherein each of the plurality of semiconductor chips includes chip pads on a first end thereof, and each of the plurality of semiconductor chips are vertically stacked and stepped such that the chip pads of the plurality of semiconductor chips are exposed.

4. The semiconductor package of claim 1, wherein the semiconductor chip structure includes:
a first semiconductor chip disposed adjacent to the package substrate having a first thickness;
second to (N−1)^{th} semiconductor chips sequentially stacked on the first semiconductor chip each having a second thickness; and
an N^{th} semiconductor chip disposed on the (N−1)^{th} semiconductor chip having a third thickness,
wherein the N^{th} semiconductor chip is the uppermost semiconductor chip, and
wherein the third thickness is equal to or greater than twice the second thickness and the third thickness is equal to or less than two and half times the second thickness, and the first thickness is greater than the second thickness.

5. The semiconductor package of claim 1, wherein the semiconductor chip structure is a first semiconductor chip structure, the semiconductor package further comprising:
at least one additional semiconductor chip structure stacked on the first semiconductor chip structure opposite to the package substrate,
wherein each of the first semiconductor chip structure and the at least one additional semiconductor chip structure includes:
a lowermost semiconductor chip having a first thickness; and
at least one intermediate semiconductor chip having a second thickness on the lowermost semiconductor chip,
wherein the first thickness is greater than the second thickness.

6. The semiconductor package of claim 5, wherein the first thickness is equal to or greater than twice the second thickness and the first thickness is equal to or less than two and half times the second thickness.

7. The semiconductor package of claim 5, wherein the first and additional semiconductor chip structures includes at least one odd-numbered semiconductor chip structure and at least one even-numbered semiconductor chip structure alternately stacked, and
wherein each of the plurality of semiconductor chips of the at least one odd-numbered semiconductor chip structure are vertically stacked and stepped toward a first direction, and each of the plurality of semiconductor chips of the at least one even-numbered semiconductor chip structure are vertically stacked stepped toward a second direction opposite to the first direction.

8. The semiconductor package of claim 1, wherein the semiconductor chip structure further comprises chip adhesion films between each of the plurality of semiconductor chips and between the package substrate and the semiconductor chip structure.

9. The semiconductor package of claim 1, further comprising:
a connection member electrically connecting the package substrate to the semiconductor chip structure; and
one or more external terminals electrically connected to the package substrate.

10-13. (canceled)

14. A semiconductor package comprising:
a package substrate;
a first semiconductor chip mounted over the package substrate;
a second semiconductor chip mounted over the first semiconductor chip, wherein a portion of the second semiconductor chip overhangs the first semiconductor chip; and
an uppermost semiconductor chip mounted over the second semiconductor chip, wherein a portion of the uppermost semiconductor chip overhangs the second semiconductor chip in a same direction that the second semiconductor chip overhangs the first semiconductor chip; and
a molding covering the first, second, and uppermost semiconductor chips and the package substrate,
wherein a thickness of the uppermost semiconductor chip is greater than an average thickness of the first and second semiconductor chips.

15. The semiconductor package of claim 14, additionally comprising one or more intervening semiconductor chips mounted over the second semiconductor chip and under the uppermost semiconductor chip, wherein a portion of each of the one or more intervening semiconductor chips overhangs each of the other semiconductor chips positioned therebelow and the thickness of the uppermost semiconductor chip is greater than an average thickness of the first, second, and intervening semiconductor chips.

16. The semiconductor package of claim 15 wherein the thickness of the uppermost semiconductor ship is equal to or greater than 1.5 times and equal to or less than 2.5 times the average thickness of the first, second, and intervening semiconductor chips.

17. The semiconductor package of claim 14, wherein the first semiconductor chip has a first thickness, the second semiconductor chip has a second thickness, and the uppermost semiconductor chip has a third thickness, wherein the third thickness is equal to or greater than twice the second thickness and equal to or less than 2.5 times the second thickness, and wherein the first thickness is greater than the second thickness.

18. The semiconductor package of claim 14, wherein a chip adhesion film is formed between the package substrate and the first semiconductor chip and between the first semiconductor chip and the second semiconductor chip.

19. The semiconductor package of claim 14 further comprising a connection member electrically connecting the package substrate to the first semiconductor chip.

20. The semiconductor package of claim 14 further comprising:
a first chip pad on the first semiconductor chip, the first chip pad not covered by the second semiconductor chip;
a second chip pad on the second semiconductor chip, the second chip pad not covered by the uppermost semiconductor chip; and
an uppermost chip pad on the uppermost semiconductor chip.
